(19) United States
(12) Patent Application Publication
(10) Pub. No.: US 2025/0326014 A1
(43) Pub. Date: Oct. 23, 2025

(54) SUBSTRATE PROCESSING SYSTEM AND SUBSTRATE PROCESSING METHOD

(71) Applicant: TOKYO ELECTRON LIMITED, Tokyo (JP)

(72) Inventor: Gentaro GOSHI, Kumamoto (JP)

(21) Appl. No.: 19/183,517

(22) Filed: Apr. 18, 2025

(30) Foreign Application Priority Data
Apr. 19, 2024 (JP) 2024-068154

(51) Int. Cl. B08B 13/00; B08B 3/04; B65G 47/90; F26B 5/00; G01K 1/02; G01K 1/024

(52) U.S. Cl. CPC B08B 13/00; B08B 3/04; B65G 47/90; F26B 5/005; G01K 1/024; G01K 1/026

(57) ABSTRACT

A substrate processing system includes a batch-type processor configured to collectively process a plurality of substrates, a single-substrate-type processor configured to process the plurality of substrates one by one, and a control circuit configured to execute: calculating a batch-type processing time including a time required for processing the plurality of substrates by the batch-type processor, based on recipe information including an procedure in which the plurality of substrates is processed; and selecting, based on correspondence information in which inspection items and inspection times in an inspection on the single-substrate-type processor are associated with each other, one or two or more of the inspection items for which the inspection times are equal to or less than the batch-type processing time, and executing the inspection on the selected one or two or more inspection items.

### CROSS-REFERENCE TO RELATED APPLICATION

This application is based upon and claims the benefit of priority from Japanese Patent Application No. 2024-068154, filed on Apr. 19, 2024, the entire contents of which are incorporated herein by reference.

### TECHNICAL FIELD

The present disclosure relates to a substrate processing system and a substrate processing method.

### BACKGROUND

A substrate processing system including a batch-type processor and a single-substrate-type processor is known (see, for example, Patent Document 1). The batch-type processor performs a batch-type processing on a lot including a plurality of substrates in a collective manner. The single-substrate-type processor performs a single-substrate-type processing on the substrates one by one. In the substrate processing system, a composite processing including the batch-type processing and the single-substrate-type processing is performed in parallel with the single-substrate-type processing.

### PRIOR ART DOCUMENT

### Patent Document

Patent Document 1: Japanese Laid-Open Patent Publication No. 2023-121571

### SUMMARY

According to one embodiment of the present disclosure, a substrate processing system includes a batch-type processor configured to collectively process a plurality of substrates, a single-substrate-type processor configured to process the plurality of substrates one by one, and a control circuit configured to execute: calculating a batch-type processing time including a time required for processing the plurality of substrates by the batch-type processor, based on recipe information including an procedure in which the plurality of substrates is processed; and selecting, based on correspondence information in which inspection items and inspection times in an inspection on the single-substrate-type processor are associated with each other, one or two or more of the inspection items for which the inspection times are equal to or less than the batch-type processing time, and executing the inspection on the selected one or two or more inspection items.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view illustrating a substrate processing system according to an embodiment.

FIG. 2 is a flowchart illustrating a substrate processing method according to an embodiment.

FIG. 3 is a diagram illustrating a flow of a substrate in the substrate processing method according to the embodiment.

FIG. 4 is a flowchart illustrating an inspection method of the substrate processing system of FIG. 1.

FIG. 5 is a diagram illustrating a flow of a substrate in the inspection method of the substrate processing system of FIG. 1.

FIG. 6 is a diagram illustrating an example of recipe information.

FIG. 7 is a diagram illustrating an example of correspondence information.

### DETAILED DESCRIPTION

Hereinafter, non-limitative exemplary embodiments of the present disclosure will be described with reference to the accompanying drawings. Throughout the accompanying drawings, the same or corresponding members or constituent elements will be denoted by the same or corresponding reference numerals, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Substrate Processing System

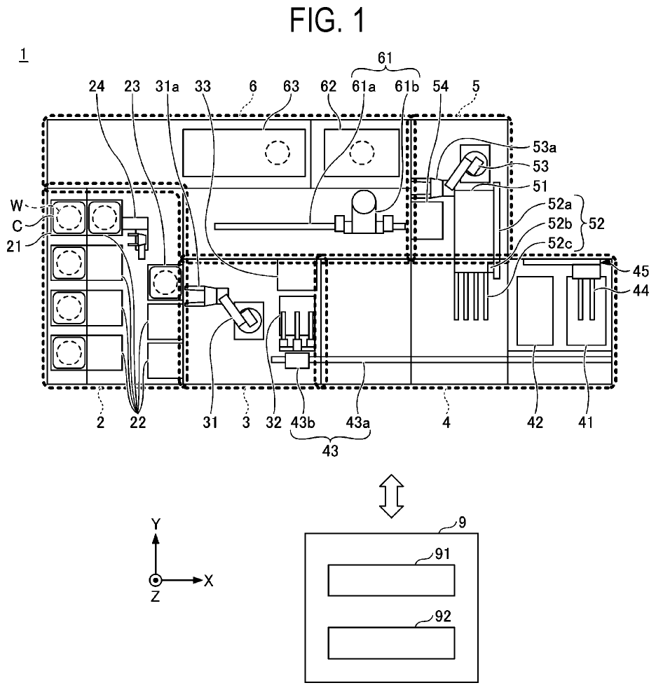

A substrate processing system according to an embodiment will now be described with reference to FIG. 1. As illustrated in FIG. 1, a substrate processing system 1 includes a loader/unloader 2, a first interface 3, a batch-type processor 4, a second interface 5, a single-substrate-type processor 6, and a control circuit 9.

The loader/unloader 2 serves as both a loader and an unloader. This downsizes the substrate processing system 1. The loader/unloader 2 includes a load port 21, a stocker 22, a loader 23, and a cassette transfer device 24.

The load port 21 is arranged in the loader/unloader 2 in a negative X-axis direction. A plurality of (for example, four) load ports 21 is arranged in a Y-axis direction. However, the number of the load ports 21 is not particularly limited. Cassettes C are placed on the load ports 21. Each cassette C accommodates plural sheets (for example, 25 sheets) of substrates W and is loaded into and unloaded from the load port 21. The substrates W are held horizontally in an interior of the cassette C and are held in a vertical direction at a second pitch P2 (P2=N×P1), which is N times a first pitch P1. N is a natural number equal to or greater than 2. N is 2 in the present embodiment but may be 3 or greater.

A plurality of (for example, four) stockers 22 is arranged in the Y-axis direction at the center of the loader/unloader 2 in an X-axis direction. The plurality of (for example, two) stockers 22 is arranged adjacent to the first interface 3 in the Y-axis direction on the side of the loader/unloader 2 in a positive X-axis direction. The stockers 22 may be arranged in multiple stages in the vertical direction. The stockers 22 temporarily store the cassette C accommodating the substrates W before a cleaning processing, the cassette C whose interior is empty after the substrates W are retrieved, the cassette C accommodating inspection substrates, the cassette C accommodating dummy substrates, and the like. Examples of the inspection substrates may include a bare wafer with no pattern on a surface thereof, a patterned wafer with a pattern on a surface thereof, and a sensor-equipped wafer with a temperature sensor. The stockers 22 may include a dedicated stocker for temporarily storing only the cassette C accommodating the inspection substrates. The stockers 22 may include a dedicated stocker for temporarily storing only the cassette C accommodating the dummy substrates. The number of the stockers 22 is not particularly limited.

The loader 23 is provided adjacent to the first interface 3 and is arranged on the side of the loader/unloader 2 in the positive X-axis direction. The cassettes C are placed on the loader 23. The loader 23 is provided with a lid opening/closing mechanism (not illustrated) for opening and closing a lid for the cassette C. A plurality of loaders 23 may be provided. The loaders 23 may be arranged in multiple stages in the vertical direction.

The cassette transfer device 24 is, for example, an articulated transfer robot. The cassette transfer device 24 transfers the cassettes C between the load port 21, the stocker 22, and the loader 23.

The first interface 3 is arranged on the side of the loader/unloader 2 in the positive X-axis direction. The first interface 3 transfers the substrates W between the loader/unloader 2, the batch-type processor 4, and the single-substrate-type processor 6. The first interface 3 includes a substrate transfer device 31, a lot former 32, and a first delivery stage 33.

The substrate transfer device 31 transfers the substrates W between the cassette C placed on the loader 23, the lot former 32, and the first delivery stage 33. The substrate transfer device 31 distributes the substrates W, which are accommodated in the cassette C placed on the loader 23, between the first delivery stage 33 for transferring the substrates W to the single-substrate-type processor 6 and the lot former 32 for transferring the substrates W to the batch-type processor 4. The substrate transfer device 31 is a multi-axis (for example, six-axis) arm robot and includes a substrate holding arm 31a at a tip thereof. The substrate holding arm 31a includes a plurality of holding hooks (not illustrated) configured to hold the plural sheets (for example, 25 sheets) of substrates W. The substrate holding arm 31a may take any position and posture in a three-dimensional space while holding the substrates W with the holding hooks.

The lot former 32 is arranged on the side of the first interface 3 in the positive X-axis direction. The lot former 32 holds the plurality of substrates W at the first pitch P1 to form a lot L.

The first delivery stage 33 is provided adjacent to the single-substrate-type processor 6 and is arranged on the side of the first interface 3 in the positive Y-axis direction. The first delivery stage 33 includes a first area on which the substrates W before processing by the single-substrate-type processor 6 are placed and a second area on which the substrates W after the processing by the single-substrate-type processor 6 are placed. The first area and the second area are arranged in the vertical direction. The second area may be provided above the first area in the vertical direction. This makes it possible to prevent the substrates after the processing from being contaminated by foreign substances falling from the substrates before the processing. In the first area, the plurality of substrates W is placed at the second pitch P2. The first area is configured to be capable of placing a first number of sheets of substrates W thereon. The first number of sheets is, for example, 25. The first number of sheets is, for example, the same number as the number of sheets of substrates W accommodated in the cassette C. In the second area, the plurality of substrates W is placed at the second pitch P2. The second area is configured to be capable of placing a second number of sheets of substrates W thereon. The second number of sheets is greater than the first number of sheets and is, for example, 50 or 100. The second number of sheets is, for example, the same number as the number of sheets of substrates W constituting the lot L. The lot L is composed of the plurality of substrates W in the cassette C. In the first area, the first delivery stage 33 receives the substrates W from the substrate transfer device 31 and temporarily stores the substrates W until the substrates W are transferred to the single-substrate-type processor 6. In the second area, the first delivery stage 33 receives the substrates W from a fourth transfer device 61 and temporarily stores the substrates W until they are transferred to the loader/unloader 2.

The batch-type processor 4 is arranged on the side of the first interface 3 in the positive X-axis direction. That is, the loader/unloader 2, the first interface 3, and the batch-type processor 4 are arranged in this order from the negative X-axis direction toward the positive X-axis direction. The batch-type processor 4 collectively processes the lot L including the plurality of (for example, 50 or 100) substrates W at the first pitch P1. One lot L is composed of, for example, M substrates W in the cassette C. M is a natural number equal to or greater than 2. M may be the same natural number as N or may be a natural number different from N. The batch-type processor 4 includes a chemical liquid tank 41, a rinse liquid tank 42, a first transfer device 43, a processing tool 44, and a driving device 45.

The chemical liquid tank 41 and the rinse liquid tank 42 are arranged in the X-axis direction. For example, the chemical liquid tank 41 and the rinse liquid tank 42 are arranged in this order from the positive X-axis direction toward the negative X-axis direction. The chemical liquid tank 41 and the rinse liquid tank 42 are also collectively referred to as a processing tank. The number of chemical liquid tanks 41 and rinse liquid tanks 42 is not limited to those illustrated in FIG. 1. For example, the chemical liquid tank 41 and the rinse liquid tank 42 may constitute one set in FIG. 1 but may constitute a plurality of sets.

The chemical liquid tank 41 stores a chemical liquid in which the lot L is immersed. The chemical liquid is, for example, an aqueous phosphoric acid solution (H₃PO₄). The aqueous phosphoric acid solution selectively etches away a silicon nitride film among a silicon oxide film and the silicon nitride film. The chemical liquid is not limited to the aqueous phosphoric acid solution. For example, the chemical liquid may be dilute hydrofluoric acid (DHF), a mixed liquid (BHF) of hydrofluoric acid and ammonium fluoride, dilute sulfuric acid, a mixed liquid (SPM) of sulfuric acid, hydrogen peroxide, and water, a mixed liquid (SC1) of ammonia, hydrogen peroxide, and water, a mixed liquid (SC2) of hydrochloric acid, hydrogen peroxide, and water, a mixed liquid (TMAH) of tetramethylammonium hydroxide and water, plating liquid, or the like. The chemical liquid may be used for a stripping processing or a plating processing. The number of chemical liquids is not particularly limited. A plurality of chemical liquids may be used.

The rinse liquid tank 42 stores a first rinse liquid in which the lot L is immersed. The first rinse liquid is pure water for removing the chemical liquid from the substrate W and is, for example, deionized water (DIW).

The first transfer device 43 includes a guide rail 43a and a first transfer arm 43b. The guide rail 43a is arranged on the negative Y-axis direction rather than on the side of the processing tank. The guide rail 43a extends in a horizontal direction (the X-axis direction) from the first interface 3 to the batch-type processor 4. The first transfer arm 43b moves in the horizontal direction (the X-axis direction) along the guide rail 43a. The first transfer arm 43b may move in the vertical direction or rotate around a vertical axis. The first transfer arm 43b collectively transfers the lot L between the first interface 3 and the batch-type processor 4.

The processing tool 44 receives the lot L from the first transfer arm 43b and holds the lot L. The processing tool 44 holds the plurality of substrates W at the first pitch P1 in the Y-axis direction and holds each of the plurality of substrates W vertically.

The driving device 45 moves the processing tool 44 in the X-axis direction and a Z-axis direction. The processing tool 44 immerses the lot L in the chemical liquid stored in the chemical liquid tank 41, immerses the lot L in the first rinse liquid stored in the rinse liquid tank 42, and then transfers the lot L to the first transfer device 43.

The number of units constituting the processing tool 44 and the driving device 45 is one in the present embodiment but a plurality of units may be provided. In the plurality of units, one unit immerses the lot L in the chemical liquid stored in the chemical liquid tank 41, and another unit immerses the lot L in the first rinse liquid stored in the rinse liquid tank 42. In this case, the driving device 45 needs to move the processing tool 44 only in the Z-axis direction and does not need to move the processing tool 44 in the X-axis direction.

The second interface 5 is arranged on the side of the batch-type processor 4 in the positive Y-axis direction. The second interface 5 transfers the substrates W between the batch-type processor 4 and the single-substrate-type processor 6. The second interface 5 includes an immersion tank 51, a second transfer device 52, a third transfer device 53, and a second delivery stage 54.

The immersion tank 51 is arranged beyond a movement range of the first transfer arm 43b. For example, the immersion tank 51 is arranged at a position shifted in the positive Y-axis direction with respect to the processing tank. The immersion tank 51 stores a second rinse liquid in which the lot L is immersed. The second rinse liquid is, for example, DIW. The substrates W are held in the second rinse liquid until they are lifted up from the second rinse liquid by the third transfer device 53. Since the substrates W are positioned below a liquid level of the second rinse liquid, a surface tension of the second rinse liquid does not act on the substrates W, which makes it possible to prevent irregular patterns of the substrates W from collapsing.

The second transfer device 52 includes a Y-axis driving device 52a, a Z-axis driving device 52b, and a second transfer arm 52c.

The Y-axis driving device 52a is arranged on the side of the second interface 5 in the positive X-axis direction. The Y-axis driving device 52a extends in the horizontal direction (in the Y-axis direction) from the second interface 5 to the batch-type processor 4. The Y-axis driving device 52a moves the Z-axis driving device 52b and the second transfer arm 52c in the Y-axis direction. The Y-axis driving device 52a may include a ball screw.

The Z-axis driving device 52b is movably attached to the Y-axis driving device 52a. The Z-axis driving device 52b moves the second transfer arm 52c in the Z-axis direction. The Z-axis driving device 52b may include a ball screw.

The second transfer arm 52c is movably attached to the Z-axis driving device 52b. The second transfer arm 52c receives the lot L from the first transfer arm 43b and holds the lot L. The second transfer arm 52c holds the plurality of substrates W at the first pitch P1 in the Y-axis direction and holds each of the plurality of substrates W in the vertical direction. The second transfer arm 52c moves in the Y-axis direction and the Z-axis direction by the Y-axis driving device 52a and the Z-axis driving device 52b. The second transfer arm 52c is configured to be movable between multiple positions including a delivery position, an immersion position, and a standby position.

The delivery position is a position at which the lot L is delivered between the first transfer arm 43b and the second transfer arm 52c. The delivery position is a position on the sides of the negative Y-axis direction and the positive Z-axis direction.

The immersion position is a position at which the lot L is immersed in the immersion tank 51. The immersion position is a position on the sides of the positive Y-axis direction and the negative Z-axis direction rather than the delivery position.

The standby position is a position at which the second transfer arm 52c waits when the lot L is not being delivered or immersed in the immersion tank 51. The standby position is directly below the delivery position (on the side of the negative Z-axis direction) and is a position that does not interfere with the movement of the first transfer arm 43b. In this case, the second transfer arm 52c may move only upward (only in the positive Z-axis direction) to move the delivery position. This improves throughput. The standby position may be the same position as the immersion position. In this case, it is possible to prevent particles, which may be generated by the operation of the first transfer device 43, from adhering to the second transfer arm 52c. The standby position may be a position directly above the immersion position (in the positive Z-axis direction). In this way, by setting the standby position to a position different from the delivery position, it is possible to prevent the first transfer arm 43b and the second transfer arm 52c from being brought into contact with each other.

The second transfer device 52 moves the second transfer arm 52c to the immersion position or the standby position while the first transfer device 43 is operating. This makes it possible to prevent the first transfer arm 43b and the second transfer arm 52c from being brought into contact with each other.

The third transfer device 53 is a multi-axis (for example, six-axis) arm robot and includes a third transfer arm 53a at a tip thereof. The third transfer arm 53a includes a holding hook (not illustrated) capable of holding one sheet of substrate W. The third transfer arm 53a may take any position and posture in a three-dimensional space while holding the substrate W with the holding hook. The third transfer device 53 transfers the substrate W between the second transfer arm 52c at the immersion position and the second delivery stage 54. In this case, the immersion tank 51 is arranged beyond a movement range of the first transfer arm 43b. Thus, the first transfer arm 43b and the third transfer arm 53a do not interfere with each other. This makes it possible to freely operate one of the first transfer device 43 and the third transfer device 53 regardless of an operating state of the other. Therefore, the first transfer device 43 and the third transfer device 53 may be operated at any timing. This shortens a time required to transfer the substrate W. Accordingly, the productivity of the substrate processing system 1 is improved.

The second delivery stage 54 is provided adjacent to the single-substrate-type processor 6 and is arranged on the side of the second interface 5 in the negative X-axis direction. The second delivery stage 54 receives the substrates W from the third transfer device 53 and temporarily stores the substrates W until they are transferred to the single-substrate-type processor 6. That is, the substrates W retrieved from the immersion tank 51 are placed on the second delivery stage 54. The substrates W placed on the second delivery stage 54 may be in a state in which the surfaces thereof are wet with the second rinse liquid. In this case, a surface tension of the second rinse liquid does not act on the substrates W. This makes it possible to suppress the irregular patterns of the substrates W from collapsing. Plural sheets (for example, two sheets) of substrates W are placed on the second delivery stage 54.

The single-substrate-type processor 6 is arranged on the side of the second interface 5 in the negative X-axis direction and on the sides of the loader/unloader 2, the first interface 3, and the batch-type processor 4 in the positive Y-axis direction. The single-substrate-type processor 6 processes the substrates W one by one. The single-substrate-type processor 6 includes the fourth transfer device 61, a liquid processing device 62, and a drying device 63.

The fourth transfer device 61 includes a guide rail 61a and a fourth transfer arm 61b. The guide rail 61a is arranged on the side of the single-substrate-type processor 6 in the negative Y-axis direction. The guide rail 61a extends in the horizontal direction (the X-axis direction) in the single-substrate-type processor 6. The fourth transfer arm 61b moves in the horizontal direction (the X-axis direction) and the vertical direction along the guide rail 61a, and rotates around a vertical axis. The fourth transfer arm 61b transfers the substrates W between the second delivery stage 54, the liquid processing device 62, the drying device 63, and the first delivery stage 33. One fourth transfer arm 61b may be provided, or a plurality of fourth transfer arms 61b may be provided. In the latter case, the fourth transfer device 61 collectively transfers plural sheets (for example, five sheets) of substrates W.

The liquid processing device 62 is arranged on the side of the single-substrate-type processor 6 in the positive X-axis direction and the side of the single-substrate-type processor 6 in the positive Y-axis direction. The liquid processing device 62 is of a single-substrate type and processes the substrates W one by one with a processing liquid. The liquid processing device 62 is arranged in multiple stages (for example, three stages) in the vertical direction (the Z-axis direction). Thus, the plurality of substrates W may be processed simultaneously with the processing liquid. A plurality of processing liquids may be provided. For example, pure water such as DIW and a drying liquid having a lower surface tension than pure water may be provided. The drying liquid may be an alcohol such as isopropyl alcohol (IPA).

The drying device 63 is arranged adjacent to the liquid processing device 62 on the negative X-axis direction. In this case, an end surface of the single-substrate-type processor 6 in the positive Y-axis direction may be arranged so as to be flush or substantially flush with an end surface of the second interface 5 in the positive Y-axis direction. Thus, almost no dead space occurs. This reduces the footprint of the substrate processing system 1. In contrast, in a case in which the drying device 63 is arranged adjacent to the liquid processing device 62 in the positive Y-axis direction, the end surface of the single-substrate-type processor 6 in the positive Y-axis direction may more protrude than the end surface of the second interface 5 in the positive Y-axis direction. This may cause a dead space. The drying device 63 is of a single-substrate type and dries the substrates W one by one with a supercritical fluid. The drying device 63 is arranged in multiple stages (for example, three stages) in the vertical direction. Thus, the plurality of substrates W may be dried simultaneously.

Both the liquid processing device 62 and the drying device 63 do not have to be of the single-substrate type, and the liquid processing device 62 may be of the single-substrate type and the drying device 63 may be of a batch type. The drying device 63 may collectively dry the plurality of substrates W with the supercritical fluid. The number of substrates W collectively processed by the drying device 63 may be equal to or greater, or be less than the number of substrates W collectively processed by the liquid processing device 62. Devices other than the liquid processing device 62 and the drying device 63 may be arranged in the single-substrate-type processor 6.

The control circuit 9 is, for example, a computer, and includes a calculator 91 such as a central processing unit (CPU), and a storage 92 such as a memory. The storage 92 stores programs for controlling various processes executed in the substrate processing system 1. The control circuit 9 controls an operation of the substrate processing system 1 by causing the calculator 91 to execute the programs stored in the storage 92.

The control circuit 9 includes electronic circuits such as the CPU, a field programmable gate array (FPGA), and an application specific integrated circuit (ASIC). The control circuit 9 executes various control operations described in this specification by executing instruction codes stored in the memory or by being designed for a specific purpose.

### Substrate Processing Method

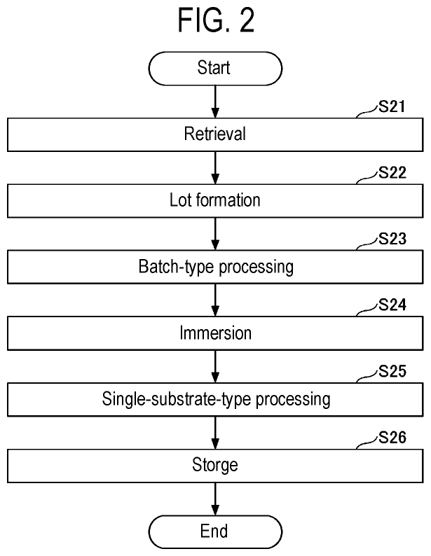

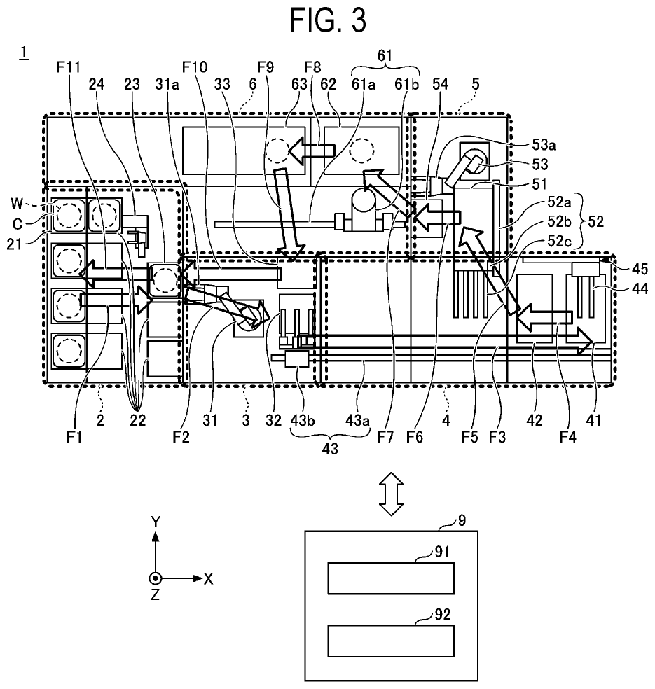

A substrate processing method according to an embodiment will now be described with reference to FIGS. 2 and 3. A process illustrated in FIG. 2 is executed under the control of the control circuit 9.

First, the cassette C accommodating the plurality of substrates W is loaded into the loader/unloader 2 and placed on the load port 21. The substrates W are, for example, product wafers. Inside the cassette C, the substrates W are held horizontally and held in the vertical direction at the second pitch P2 (P2=N×P1). N is a natural number of 2 or more, which is 2 in the present embodiment but may be 3 or more.

Subsequently, the cassette transfer device 24 transfers the cassette C from the load port 21 to the loader 23 (as indicated by an arrow F1 in FIG. 3). When the cassette C is transferred to the loader 23, the lid of the cassette C is open by the lid opening/closing mechanism.

Subsequently, the control circuit 9 controls individual constituent elements of the substrate processing system 1 so as to execute the process illustrated in FIG. 2. The control circuit 9 controls individual constituent elements of the substrate processing system 1 so as to execute the process illustrated in FIG. 2 each time the cassette C is placed on the loader 23.

First, the control circuit 9 controls individual constituent elements of the substrate processing system 1 so as to transfer the substrates W accommodated in the cassette C to the batch-type processor 4 (Step S21 in FIG. 2). Specifically, the substrate transfer device 31 receives the substrates W accommodated in the cassette C and transfers the same to the lot former 32 (as indicated by an arrow F2 in FIG. 3).

Subsequently, the lot former 32 holds the plurality of substrates W at the first pitch P1 (P1=P2/N) to form the lot L (Step S22 in FIG. 2). One lot L is composed of, for example, M substrates W in the cassette C. The pitch between the substrates W narrows from the second pitch P2 to the first pitch P1. Thus, the number of substrates W to be collectively processed may be increased. Subsequently, the first transfer device 43 receives the lot L from the lot former 32 and transfers the same to the processing tool 44 (as indicated by an arrow F3 in FIG. 3).

Subsequently, the processing tool 44 descends from above the chemical liquid tank 41, immerses the lot L in the chemical liquid, and performs a chemical processing (Step S23 in FIG. 2). Thereafter, the processing tool 44 rises to lift up the lot L from the chemical liquid and then moves in the horizontal direction (the negative X-axis direction) upward of the rinse liquid tank 42 (as indicated by an arrow F4 in FIG. 3).

Subsequently, the processing tool 44 descends from above the rinse liquid tank 42, immerses the lot L in the first rinse liquid, and performs a rinse liquid processing (Step S23 in FIG. 2). Thereafter, the processing tool 44 rises to lift up the lot L from the first rinse liquid. Subsequently, the first transfer device 43 receives the lot L from the processing tool 44 and transfers the same to the second transfer device 52.

Subsequently, the second transfer arm 52c of the second transfer device 52 moves in the horizontal direction (the positive Y-axis direction) and descends from above the immersion tank 51 to immerse the lot L in the second rinse liquid (Step S24 in FIG. 2; as indicated by an arrow F5 in FIG. 3). The plural sheets of substrates W of the lot L are held in the second rinse liquid until they are lifted up from the second rinse liquid by the third transfer device 53. Since the substrates W are below a liquid level of the second rinse liquid, the surface tension of the second rinse liquid does not act on the substrates W, thereby preventing the irregular patterns of the substrates W from collapsing.

Subsequently, the third transfer device 53 transfers the substrates W of the lot L held by the second transfer arm 52c in the second rinse liquid to the second delivery stage 54 (as indicated by an arrow F6 in FIG. 3). The third transfer device 53 transfers the substrates W one by one to the second delivery stage 54.

Subsequently, the fourth transfer device 61 receives the substrates W from the second delivery stage 54 and transfers the same to the liquid processing device 62 (as indicated by an arrow F7 in FIG. 3).

Subsequently, the liquid processing device 62 processes the substrates W one by one with a liquid (Step S25 in FIG. 2). A plurality of liquids may be used. For example, pure water such as DIW and a drying liquid having a lower surface tension than pure water may be used. The drying liquid may be an alcohol such as IPA. The liquid processing device 62 supplies the pure water and the drying liquid in this order to upper surfaces of the substrates W to form a liquid film of the drying liquid.

Subsequently, the fourth transfer device 61 receives the substrates W from the liquid processing device 62 and holds the same horizontally with the liquid film of the drying liquid facing upward. The fourth transfer device 61 transfers the substrates W from the liquid processing device 62 to the drying device 63 (as indicated by an arrow F8 in FIG. 3).

Subsequently, the drying device 63 dries the substrates W one by one with a supercritical fluid (Step S25 in FIG. 2). The drying liquid may be replaced with the supercritical fluid, which suppresses the irregular patterns of the substrates W from collapsing due to the surface tension of the drying liquid may be suppressed. The supercritical fluid requires a pressure-resistant container. Thus, in order to downsize the pressure-resistant container, the substrates W need to be processed in a single-substrate-type processing manner rather than a batch-type processing manner.

In the present embodiment, the drying device 63 is of a single substrate type but, as described above, may be of a batch type. The drying device 63 of the batch type collectively dries, with the supercritical fluid, the plurality of substrates W on which the liquid film has been formed. The drying device 63 of the single substrate type includes one transfer arm to hold the substrates W, whereas the drying device 63 of the batch type includes a plurality of transfer arms to hold the substrates W.

While the drying device 63 of the present embodiment dries the substrates W with the supercritical fluid, the drying method is not particularly limited. The drying method may be any method as long as it can suppress the collapse of the irregular patterns of the substrate W. Examples of the drying method may include a spin drying, a scan drying, a water-repellent drying, and the like. The spin drying includes removing the liquid film from the substrate W by virtue of a centrifugal force caused by rotating the substrate W. The scan drying includes dropping the liquid film from the substrate W by virtue of the centrifugal force caused by rotating the substrate W while the supply position of the drying liquid is moved from the center of the substrate W to an outer periphery of the substrate W. Further, the scan drying may include moving a supply position of a drying gas, such as a N₂ gas, from the center of the substrate W toward the outer periphery of the substrate W so as to follow the supply position of the drying liquid.

Subsequently, the fourth transfer device 61 receives the substrates W from the drying device 63 and transfers the same to the first delivery stage 33 (as indicated by an arrow F9 in FIG. 3).

Subsequently, the substrate transfer device 31 receives the substrates W from the first delivery stage 33 and stores the same in the cassette C placed on the loader 23 (Step S26 in FIG. 2; as indicated by an arrow F10 in FIG. 3).

Subsequently, the cassette transfer device 24 transfers the cassette C from the loader 23 to the load port 21 (as indicated by an arrow F11 in FIG. 3). The cassette C transferred to the load port 21 is unloaded from the loader/unloader 2 in a state in which the plurality of substrates W is stored therein. The cassette transfer device 24 may transfer the cassette C from the loader 23 to the stockers 22 and temporarily store the cassette C in the stockers 22.

### Inspection Method of Substrate Processing System

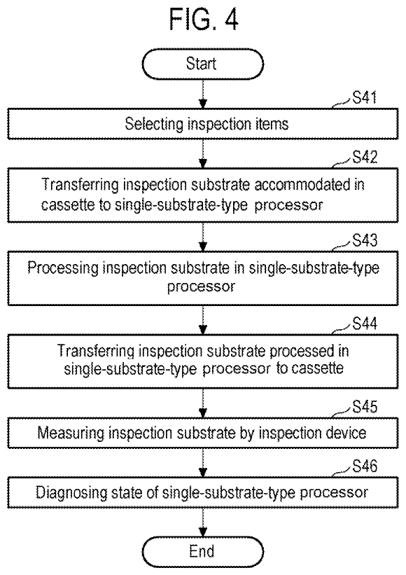

An inspection method of the substrate processing system 1 according to an embodiment will now be described with reference to FIGS. 4 to 7. A process illustrated in FIG. 4 is executed under the control of the control circuit 9. In the process illustrated in FIG. 4, the state of the single-substrate-type processor 6 is diagnosed. The process illustrated in FIG. 4 is executed, for example, while the plurality of substrates W is being processed by the batch-type processor 4.

First, the control circuit 9 calculates a batch-type processing time based on recipe information and then selects one or two or more inspection items having inspection times equal to or less than the batch-type processing time, based on correspondence information in which inspection items and inspection times are associated with each other (Step S41 in FIG. 4). The correspondence information may include priorities associated with the inspection items. In this case, the control circuit 9 may select the inspection items based on the priorities and the inspection times, and execute the inspection on the selected inspection items.

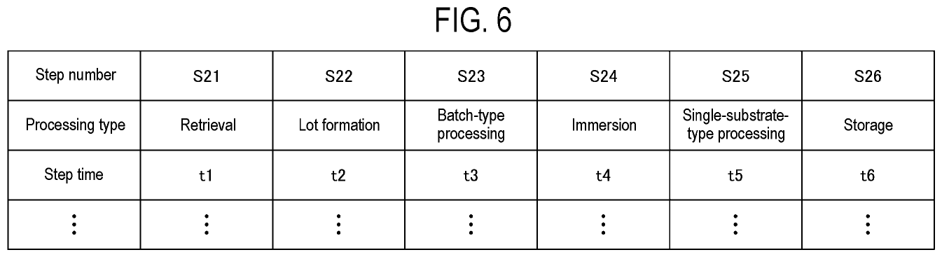

The recipe information includes a procedure in which the processing on the substrates W is executed. As illustrated in FIG. 6, the recipe information includes, for example, Step number, Processing type, and Step time. Processing type and Step time are associated with the step number. Step number includes Step S21, Step S22, Step S23, Step S24, Step S25, and Step S26. Processing type includes Retrieval, Lot formation, Batch-type processing, Immersion, Single-substrate-type processing, and Storage. Step time includes Time t1, Time t2, Time t3, Time t4, Time t5, and Time t6. For example, the recipe information is prepared for each product specification. The product specification includes, for example, the number of stacked cells of a NAND flash memory having a three-dimensional cell structure. For example, the more the number of stacked layers, the greater Time t3 required for the batch-type processing in Step S23.

Such a batch-type processing time includes a time required for the processing of the batch-type processor 4. In the example of FIG. 6, the time required for the processing of the batch-type processor 4 is Time t3. Time t3 includes a time period from a time point at which the chemical processing for the lot L by the batch-type processor 4 begins to a time point at which the rinse liquid processing for the lot L ends. Time t3 may include a time period from a time point at which the first transfer device 43 receives the lot L from the lot former 32 to a time point at which the first transfer device 43 delivers the lot L to the processing tool 44.

The batch-type processing time may include a time required for lot formation. In this case, the inspection time for the single-substrate-type processor 6 may be extended. In the example of FIG. 6, the time required for lot formation is Time t2. Time t2 includes a time during which the lot former 32 forms the lot L.

The batch-type processing time may include a time for which the lot L is immersed in the immersion tank 51. In this case, the inspection time for the single-substrate-type processor 6 may be extended. In the example of FIG. 6, the time for which the lot L is immersed in the immersion tank 51 is Time t4. Time t4 includes a time period from a time point at which the second transfer device 52 receives the lot L to a time point at which the third transfer device 53 lifts up the first substrate W of the lot L from the second rinse liquid.

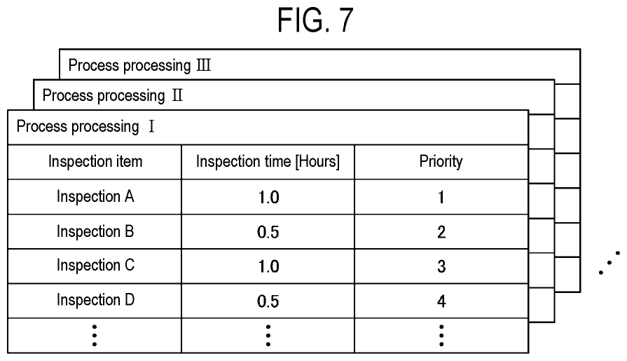

The correspondence information is prepared for, for example, a type of each process processing. The type of the process processing is a type of processing on the plurality of substrates W being processed by the batch-type processor 4. As illustrated in FIG. 7, the process processing includes, for example, Process processing I, Process processing II, and Process processing II. In Process processing I, the correspondence information includes Inspection item, Inspection time, and Priority. Inspection time and Priority are associated with Inspection item. Even in Process processing II and Process processing III, the correspondence information includes Inspection item, Inspection time, and Priority, as in Process processing I. Process processing II and Process processing III may include Inspection item, Inspection time, and Priority that are different from those in Process processing I.

Inspection item includes items of inspection for the single-substrate-type processor 6. In an example of FIG. 7, Inspection item includes Inspection A, Inspection B, Inspection C, and Inspection D. Inspection time is a time required to execute the inspection on a corresponding inspection item. In the example of FIG. 7, Inspection time includes 1.0 hours, 0.5 hours, 1.0 hours, and 0.5 hours. Priority indicates an inspection priority of a corresponding inspection item. In the example of FIG. 7, Priority includes 1, 2, 3, and 4. Priority decreases in the order numbered by 1, 2, 3, and 4.

For example, when the type of the process processing is Process processing I and the batch-type processing time is 2.5 hours, the control circuit 9 selects one or two or more inspection items in the order of increasing the priority so that the total inspection time is 2.5 hours or less. That is, the control circuit 9 selects Inspection A, Inspection B, and Inspection C. For example, when the type of the process processing is Process processing I and the batch-type processing time is 3.0 hours, the control circuit 9 selects one or two or more inspection items in the order of increasing the priority so that the total inspection time is 3.0 hours or less. That is, the control circuit 9 selects Inspection A, Inspection B, Inspection C, and Inspection D.

Examples of the inspection item may include a particle inspection, a transfer particle inspection, a pattern collapse inspection, a temperature inspection, and a dummy processing. The inspection item may further include other inspections.

The particle inspection is performed using a particle inspection substrate as an inspection substrate. The particle inspection substrate is, for example, a bare wafer with no pattern on a surface thereof. The particle inspection includes diagnosing a state of the drying device 63 based on the number of particles on the bare wafer, which changes when the bare wafer is processed by the drying device 63. For example, the control circuit 9 calculates a difference between the number of particles on the bare wafer after being processed by the drying device 63 and the number of particles on the bare wafer before being processed by the drying device 63, and diagnoses that the drying device 63 is abnormal when the difference is greater than a threshold. The number of particles may be measured by, for example, a wafer defect inspection device provided separately from the substrate processing system 1.

The transfer particle inspection is performed using the particle inspection substrate as the inspection substrate, similarly to the particle inspection. The particle inspection substrate is, for example, the bare wafer with no pattern on the surface thereof. The transfer particle inspection includes diagnosing a state of the fourth transfer device 61 based on the number of particles on the bare wafer, which changes when the bare wafer is transferred to the fourth transfer device 61. For example, the control circuit 9 calculates a difference between the number of particles on the bare wafer repeatedly transferred by the fourth transfer device 61 and the number of particles on the bare wafer before being transferred by the fourth transfer device 61. Subsequently, the control circuit 9 diagnoses that the fourth transfer device 61 is abnormal when the difference is greater than a threshold. The number of particles may be measured by, for example, the wafer defect inspection device provided separately from the substrate processing system 1.

The pattern collapse inspection is performed using a collapse inspection substrate as the inspection substrate. The collapse inspection substrate is, for example, a patterned wafer with a pattern on a surface thereof. The patterned wafer is, for example, a wafer having the same pattern as that of the product wafer on the surface thereof. The pattern is, for example, a shallow trench isolation (STI) pattern. The pattern may be a pillar pattern. The pattern collapse inspection includes diagnosing a state of the drying device 63 based on a state of the pattern on the bare wafer, which changes when the patterned wafer is processed by the drying device 63. For example, the control circuit 9 calculates the number of pattern collapses or a collapse rate caused when the patterned wafer is processed by the drying device 63, based on a surface image of the patterned wafer after being processed by the drying device 63 and a surface image of the patterned wafer before being processed by the drying device 63. Subsequently, the control circuit 9 diagnoses that the drying device 63 is abnormal when the calculated number of pattern collapses or the collapse rate is greater than a threshold. The surface image of the patterned wafer may be acquired by, for example, an image inspection device provided separately from the substrate processing system 1. The image inspection device is, for example, a scanning electron microscope (SEM).

The temperature inspection is performed using a temperature inspection substrate as the inspection substrate. The temperature inspection substrate is, for example, a sensor-equipped wafer with a temperature sensor. The sensor-equipped wafer may have a plurality of temperature sensors in the plane of the wafer. The temperature sensor is, for example, a wireless temperature sensor. In this case, the temperature sensor may transmit information on the detected temperature to the control circuit 9 in a wireless manner. The temperature inspection includes diagnosing a state of the drying device 63 based on the temperature detected by the temperature sensor of the sensor-equipped wafer loaded into the drying device 63. The temperature inspection is performed in a state in which the interior of the drying device 63 is kept in an atmospheric pressure. In this case, abnormality of a sealing material such as an O-ring provided in the drying device 63 may be detected.

The dummy processing is performed using a dummy substrate as the inspection substrate. The dummy processing includes a process of passing a large number of dummy substrates through the drying device 63 to increase a degree of cleanliness of the drying device 63.

In the correspondence information illustrated in FIG. 7, for example, Inspection A is the dummy processing, Inspection B is the particle inspection, Inspection C is the pattern collapse inspection, and Inspection D is the temperature inspection.

Subsequently, the control circuit 9 executes the inspection on the selected one or two or more inspection items. At a time point at which the inspection begins, for example, the cassette C accommodating the inspection substrate, which is used for the inspection on each inspection item and from which various states (for example, the number of particles and the surface image) before being processed by the single-substrate-type processor 6 are previously measured, may be stored in the stocker 22 in advance. In this case, the time required for each inspection may be shortened. When the cassette C accommodating the inspection substrate is not present in the stocker 22, the cassette C accommodating the inspection substrate is loaded from the load port 21.

When performing the inspection on the selected one or two or more inspection items, the control circuit 9 may change the order of the inspections on the selected one or two or more inspection items. For example, the control circuit 9 may lastly perform the dummy processing among the inspections on the one or two or more inspection items. In this case, when the plurality of substrates W processed by the batch-type processor 4 is processed in the drying device 63, the drying device 63 is in a high cleanliness state.

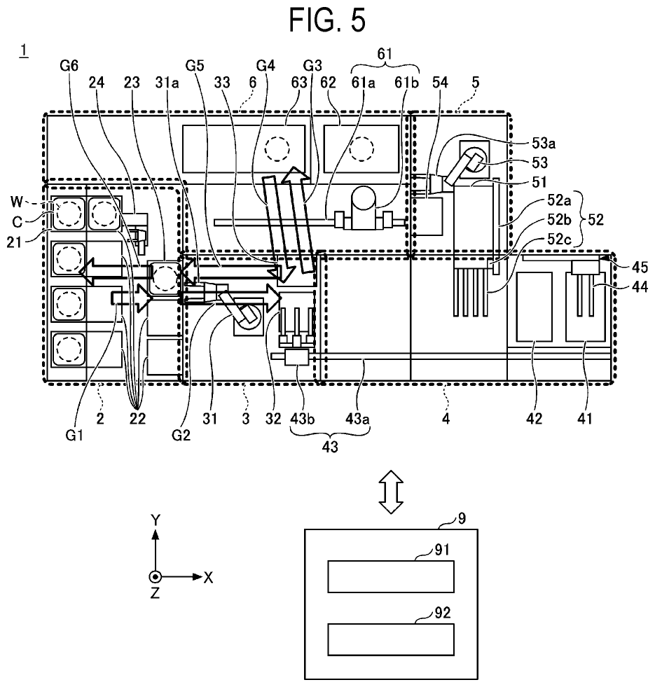

First, the control circuit 9 controls individual constituent elements of the substrate processing system 1 so as to transfer the inspection substrate accommodated in the cassette C to the single-substrate-type processor 6 (Step S42 in FIG. 4). Specifically, the cassette transfer device 24 transfers the cassette C accommodating the inspection substrate from the stocker 22 to the loader 23 (as indicated by an arrow G1 in FIG. 5). When the cassette C is transferred to the loader 23, the lid of the cassette C is open by the lid opening/closing mechanism. Subsequently, the substrate transfer device 31 receives the inspection substrate accommodated in the cassette C and transfers the same to the first delivery stage 33 (as indicated by an arrow G2 in FIG. 5). Subsequently, the fourth transfer device 61 receives the inspection substrate from the first delivery stage 33 and transfers the same to the drying device 63 (as indicated by an arrow G3 in FIG. 5).

Subsequently, the control circuit 9 controls individual constituent elements of the substrate processing system 1 so that the single-substrate-type processor 6 processes the inspection substrate (Step S43 in FIG. 4). Specifically, the drying device 63 performs a predetermined process on the inspection substrate. The predetermined process may be the same as the process of drying the substrate W with the supercritical fluid in Step S25 of the substrate processing method described above.

Thereafter, the control circuit 9 controls individual constituent elements of the substrate processing system 1 so as to transfer the inspection substrate processed by the single-substrate-type processor 6 to the cassette C (Step S44 in FIG. 4). Specifically, the fourth transfer device 61 receives the inspection substrate from the drying device 63 and transfers the same to the first delivery stage 33 (as indicated by an arrow G4 in FIG. 5). Subsequently, the substrate transfer device 31 receives the inspection substrate from the first delivery stage 33 and stores the same in the cassette C placed on the loader 23 (as indicated by an arrow G5 in FIG. 5). Subsequently, the cassette transfer device 24 transfers the cassette C from the loader 23 to the load port 21 (as indicated by an arrow G6 in FIG. 5). The cassette C transferred to the load port 21 is unloaded from the loader/unloader 2 in a state in which the inspection substrate is stored in the cassette C. The unloaded inspection substrate is transferred to an inspection device (for example, the wafer defect inspection device or the image inspection device) provided separately from the substrate processing system 1, and various states (for example, the number of particles and the surface image) after the processing are measured (Step S45 in FIG. 4).

Subsequently, the control circuit 9 diagnoses a state of the single-substrate-type processor 6 based on various states of the inspection substrate before the processing and the various states of the inspection substrate after the processing (Step S46 in FIG. 4). The control circuit 9 may diagnose the state of the single-substrate-type processor 6 using a machine learning model. The state of the single-substrate-type processor 6 may include, for example, the state of the drying device 63. The state of the single-substrate-type processor 6 may include the state of the fourth transfer device 61. The state of the single-substrate-type processor 6 may include the state of the liquid processing device 62.

When the state of the drying device 63 is diagnosed to be abnormal, the control circuit 9 may set the drying device 63 diagnosed to be abnormal to be in an unusable state. The control circuit 9 may change a transfer schedule so that the substrates W are not transferred to the drying device 63 in the unusable state. The transfer schedule is defined by arranging a transfer destination and transfer order of each substrate W in time series. When changing the transfer schedule, the control circuit 9 may recalculate an expected time at which the processing on the plurality of substrates W by the substrate processing system 1 ends, and transmit the recalculated expected time to a host computer or the like, which is capable of communicating with the control circuit 9.

When the state of the drying device 63 is diagnosed to be abnormal, the control circuit 9 may notify a manager of the substrate processing system 1 of information that specifies the drying device 63 diagnosed to be abnormal. In this case, the manger may perform a maintenance work such as replacing a component of the drying device 63 diagnosed to be abnormal. This may shorten a time required to restore the drying device 63 diagnosed to be abnormal. After the maintenance work for the drying device 63 diagnosed to be abnormal is completed, the control circuit 9 may control individual constituent elements of the substrate processing system 1 so as to transfer an inspection substrate to the drying device 63 and perform the inspection on the inspection substrate while the plurality of substrates W is processed by the batch-type processor 4 and the single-substrate-type processor 6. In this case, when the drying device 63 on which the maintenance work has been performed is diagnosed to be normal, the control circuit 9 may set the drying device 63 in the unusable state to one in a usable state.

When the processing relating to Steps S41 to S46 ends, the control circuit 9 controls individual constituent elements of the substrate processing system 1 so as to start the processing by the single-substrate-type processor 6 on the plurality of substrates W processed by the batch-type processor 4.

When the processing of the single-substrate-type processor 6 on the plurality of substrates W ends, the control circuit 9 may generate data in which a state diagnosis result of the single-substrate-type processor 6 in Step S46 and the yield of the plurality of substrates W processed by the single-substrate-type processor 6 after the diagnosis are associated with each other. The control circuit 9 may store the generated data in the storage 92. The control circuit 9 may use the generated data to train the machine learning model used in Step S46.

Meanwhile, several hours may be taken from when the processing of the batch-type processor 4 on the plurality of substrates W begins till when the processing of the single-substrate-type processor begins. For this reason, even if the individual constituent elements of the single-substrate-type processor 6 is in a normal state before the processing on the plurality of substrates W by the batch-type processor 4 begins, an abnormality may occur in some of the individual constituent elements from when the processing of the batch-type processor 4 on the plurality of substrates W begins till when the processing of the single-substrate-type processor begins. In a case in which an abnormality in some of the individual constituent elements cannot be detected by the sensor or the like, when the substrates W are processed by the respective constituent elements in the abnormal state, a deterioration in yield may be caused.

In contrast, the substrate processing system 1 according to the present embodiment includes the batch-type processor 4, the single-substrate-type processor 6, and the control circuit 9. The control circuit 9 calculates the batch-type processing time based on the recipe information. The control circuit 9 selects one or two or more inspection items having the inspection times equal to or less than the batch-type processing time, based on the corresponding information in which the inspection items and the inspection times of the inspection on the single-substrate-type processor 6 are associated with each other, and executes the inspection on the selected one or two or more inspection items. In this case, the inspection may be executed in a time not exceeding the batch-type processing time immediately before the plurality of substrates W processed by the batch-type processor 4 is processed by the single-substrate-type processor 6. Further, the inspection may be preferentially executed on inspection items that are likely to cause the deterioration in yield. Therefore, the respective constituent element diagnosed to be abnormal while the plurality of substrates W is being processed by the batch-type processor 4 may be set to be in an unusable state. This makes it possible to improve both productivity and yield.

According to the present disclosure in some embodiments, it is possible to achieve an improvement in yield.

It should be noted that the embodiments disclosed herein are exemplary in all aspects and are not restrictive. The above-described embodiments may be omitted, replaced, or modified in various forms without departing from the scope and spirit of the appended claims.

What is claimed is:

1. A substrate processing system, comprising:
a batch-type processor configured to collectively process a plurality of substrates;
a single-substrate-type processor configured to process the plurality of substrates one by one; and
a control circuit configured to execute:
calculating a batch-type processing time including a time required for processing the plurality of substrates by the batch-type processor, based on recipe information including an procedure in which the plurality of substrates is processed; and
selecting, based on correspondence information in which inspection items and inspection times in an inspection on the single-substrate-type processor are associated with each other, one or two or more of the inspection items for which the inspection times are equal to or less than the batch-type processing time, and executing the inspection on the selected one or two or more inspection items.

2. The substrate processing system of claim 1, wherein the inspection is executed while the batch-type processor processes the plurality of substrates.

3. The substrate processing system of claim 1, further comprising: a loader/unloader into/from which a cassette that accommodates an inspection substrate is loaded/unloaded,
wherein the inspection includes:
transferring the inspection substrate accommodated in the cassette to the single-substrate-type processor;
processing the inspection substrate by the single-substrate-type processor;
transferring the inspection substrate processed by the single-substrate-type processor to the cassette; and
inspecting the inspection substrate transferred to the cassette.

4. The substrate processing system of claim 3, wherein the inspection substrate is a bare wafer having no pattern on a surface thereof, and
wherein the inspection includes diagnosing a state of the single-substrate-type processor based on a number of particles adhering to the bare wafer.

5. The substrate processing system of claim 3, wherein the inspection substrate is a patterned wafer having a pattern on a surface thereof, and
wherein the inspection includes diagnosing a state of the single-substrate-type processor based on a state of the pattern of the patterned wafer.

6. The substrate processing system of claim 3, wherein the inspection substrate is a sensor-equipped wafer with a temperature sensor, and
wherein the inspection includes diagnosing a state of the single-substrate-type processor based on a temperature detected by the sensor-equipped wafer.

7. The substrate processing system of claim 1, further comprising: an interface configured to transfer the plurality of substrates between the batch-type processor and the single-substrate-type processor,
wherein the interface includes an immersion tank in which the plurality of substrates processed by the batch-type processor wait while being immersed in a rinse liquid, and
wherein the batch-type processing time includes a time for which the plurality of substrates wait in the immersion tank.

8. The substrate processing system of claim 1, wherein the correspondence information includes priorities associated with the inspection items, and
wherein the control circuit selectively executes the inspection on the inspection items based on the priorities.

9. The substrate processing system of claim 1, wherein the control circuit changes a transfer schedule of the plurality of substrates processed by the batch-type processor based on a result of the inspection.

10. The substrate processing system of claim 1, wherein the single-substrate-type processor includes a drying device configured to dry the plurality of substrates with a supercritical fluid, and
wherein the inspection includes diagnosing a state of the drying device.

11. A substrate processing method used in a substrate processing system,
wherein the substrate processing system includes:
a batch-type processor configured to collectively process a plurality of substrates; and
a single-substrate-type processor configured to process the plurality of substrates one by one,
the substrate processing method comprising:
calculating a batch-type processing time including a time required for processing the plurality of substrates by the batch-type processor, based on recipe information including an procedure in which the plurality of substrates is processed; and
selecting, based on correspondence information in which inspection items and inspection times in an inspection on the single-substrate-type processor are associated with each other, one or two or more of the inspection items for which the inspection times are equal to or less than the batch-type processing time, and executing the inspection on the selected one or two or more inspection items.
